(19) United States
(12) Patent Application Publication
(10) Pub. No.: US 2022/0321987 A1
(43) Pub. Date: Oct. 6, 2022

(54) MANAGEMENT METHOD AND DEVICE OF BLUETOOTH® EARPHONE CHARGING PATHS, AND NON-TRANSITORY READABLE STORAGE MEDIUM

(71) Applicant: GOERTEK INC., Weifang City (CN)

(72) Inventors: Wenfeng LI, Weifang City (CN); Zhenpeng HAN, Weifang City (CN)

(21) Appl. No.: 17/843,063

(22) Filed: Jun. 17, 2022

Related U.S. Application Data
(63) Continuation of application No. PCT/CN2020/124771, filed on Oct. 29, 2020.

(30) Foreign Application Priority Data
Dec. 31, 2019 (CN) 201911424514.9

(51) Int. Cl. H04R 1/10; H02J 7/00

(52) U.S. Cl. CPC H04R 1/1025; H02J 7/00716; H02J 7/0048; H02J 7/0069; H02J 7/00034

(57) ABSTRACT

Disclosed are a management method and device of Bluetooth® earphone charging paths, and a non-transitory readable storage medium, which detects that an external power supply is connected, acquires an electric power level of the charging box, judges whether the electric power level of the charging box is lower than a minimum working power threshold, closes a charging function of earphones and charges the charging box through the external power supply in responding to that the electric power level of the charging box is lower than the minimum working power threshold.

### CROSS REFERENCE TO RELATED APPLICATIONS

The present application is a continuation application of International Application No. PCT/CN2020/124771, filed on Oct. 29, 2020, which claims priority to Chinese patent application No. 201911424514.9, entitled “MANAGEMENT METHOD AND DEVICE OF BLUETOOTH® EARPHONE CHARGING PATHS, AND READABLE STORAGE MEDIUM” and filed on Dec. 31, 2019, the entire contents of the aforementioned applications are incorporated herein for reference.

### TECHNICAL FIELD

The present application relates to the technical field of Bluetooth® communication, in particular to a management method of Bluetooth® earphone charging paths, a management device of Bluetooth® earphone charging paths and a non-transitory readable storage medium.

### BACKGROUND

The TWS Bluetooth® earphone is convenient for wearing and can be used alone, and therefore is used by more and more users. At current the TWS earphone generally includes two earphones and a charging box. The charging box mainly has two functions: one is to provide communication between the two earphones; and the another is to provide a function of charging for the two earphones. Therefore, if the charging box cannot work normally due to low power, the TWS earphone cannot communicate, and the normal use cannot be realized. Therefore, how to prevent the Bluetooth® earphone from not being normally used due to the low power of the charging box is an urgent technical problem to be solved at present.

### SUMMARY

The main purpose of the present application is to provide a management method of Bluetooth® earphone charging paths and a management device of Bluetooth® earphone charging paths and a readable storage medium, and aims to solve the technical problem that the Bluetooth® earphone cannot be normally used due to the low electric power of the charging box.

In order to achieve the above purpose, the present application provides a management method of Bluetooth® earphone charging paths including:
upon detecting that an external power supply is connected, acquiring an electric power level of a charging box, and judging whether the electric power level of the charging box is lower than a minimum working power threshold; and
in responding to that the electric power level of the charging box is lower than the minimum working power threshold, closing a charging function of earphones, and charging the charging box by the external power supply.

Optionally, the in responding to that the electric power level of the charging box is lower than the minimum working power threshold, closing the charging function of the earphones, and charging the charging box by the external power supply includes:
in responding to that the electric power level of the charging box is lower than the minimum working power threshold, marking a charging flag bit of the charging box and/or the earphones with a first identifier; and
upon detecting that the charging flag bit is marked with the first identifier, closing the charging function of the earphones, and charging the charging box by the external power supply.

Optionally, the upon detecting that the external power supply is connected, acquiring the electric power level of the charging box, and judging whether the electric power level of the charging box is lower than the minimum working power threshold includes:
upon detecting that the external power supply is connected, judging whether a charging current of the external power supply is smaller than a charging current required by the earphones; and
in responding to that the charging current of the external power supply, is smaller than the charging current required by the earphones, executing the acquiring the electric power level of the charging box, and judging whether the electric power level of the charging box is lower than the minimum working power threshold.

Optionally, after the in responding to that the electric power level of the charging box is lower than the minimum working power threshold, closing the charging function of earphones, and charging the charging box by the external power supply, the method further includes:
upon detecting that the electric power level of the charging box after being charged is greater than a first preset electric power threshold, marking the charging flag bit with a second identifier, and closing a charging function of the charging box;
upon detecting that the charging flag bit is marked with the second identifier, starting the charging function of the earphones, and charging the earphones by the external power supply and the charging box, wherein the first preset electric power threshold is greater than the minimum working power threshold.

Optionally, after the upon detecting that the external power supply is connected, judging whether the charging current of the external power supply is smaller than the charging current required by the earphones, the method further includes:
in responding to that the charging current of the external power supply is not smaller than the charging current required by the earphones, charging the earphones and the charging box by the external power supply.

Optionally, after the upon detecting that the external power supply is connected, acquiring the electric power level of the charging box, and judging whether the electric power level of the charging box is lower than the minimum working power threshold, the method further includes:
in responding to that the electric power level of the charging box is not lower than the minimum working power threshold, marking the charging flag bit with a second identifier, and closing a charging function of the charging box; and
upon detecting that the charging flag bit is marked with the second identifier, starting the charging function of the earphones, and charging the earphones by the external power supply and the charging box.

Optionally, after the upon detecting that the charging flag bit is marked with the second identifier, starting the charging function of the earphones, and charging the earphones by the external power supply and the charging box, the method further includes:
acquiring the electric power level of the charging box after charging the earphones, and judging whether the electric power level of the charging box after charging the earphones is lower than a second preset electric power threshold, wherein the second preset electric power threshold is less than the first preset electric power threshold and greater than the minimum working power threshold;
in responding to that the electric power level of the charging box after charging the earphones is lower than the second preset electric power threshold, marking the charging flag bit with the first identifier; and
upon detecting that the charging flag bit is marked with the first identifier, closing the charging function of the earphones, starting the charging function of the charging box, and charging the charging box by the external power supply.

Optionally, the management method of the Bluetooth® earphone charging paths further includes:
upon detecting a disconnection instruction of the external power supply, acquiring a electric power level of the earphones, acquiring the electric power level of the charging box in responding to that the electric power level of the earphones is lower than a maximum electric power threshold of the earphones, and judging whether the electric power level of the charging box is lower than the minimum working power threshold; and
in responding to that the electric power level of the charging box is lower than the minimum working power threshold, closing the charging function of the earphones to prevent the electric power of the charging box from being consumed.

In addition, in order to achieve the above purpose, the present application further provides a management device of Bluetooth® earphone charging paths. The management device of the Bluetooth® earphone charging paths includes a processor, a memory, and a management program of the Bluetooth® earphone charging paths stored in the memory and executable by the processor, when the management program of the Bluetooth® earphone charging paths is executed by the processor, the operations of the management method of the Bluetooth® earphone charging paths as described above are implemented.

In addition, in order to achieve the above purpose, the present application further provides a non-transitory computer readable storage medium, a management program of Bluetooth® earphone charging paths is stored in the computer readable storage medium, when the management program of the Bluetooth® earphone charging paths is executed by a processor, the operations of the management method of the Bluetooth® earphone charging paths.

The present application provides a management method of Bluetooth® earphone charging paths. The management method of the Bluetooth® earphone charging paths detects that an external power supply is connected, acquires an electric power level of the charging box, judges whether the electric power level of the charging box is lower than a minimum working power threshold, closes a charging function of earphones and charges the charging box through the external power supply in responding to that the electric power level of the charging box is lower than the minimum working power threshold. In this way, when the external power supply is connected for charging, the state of the charging box is determined first. In order to prevent the Bluetooth® earphone from being unable to communicate due to the low electric power of the charging box, when the electric power level of the charging box is lower than the minimum working power threshold, that is, the electric power of the charging box is insufficient, the charging box is preferentially charged, and the charging function of the earphones is closed, so that the electric power of the charging box is prevented from being further consumed by the earphones. Therefore, the charging paths for the Bluetooth® earphone and the charging box are switched in real time based on the electric power of the charging box, the electric power of the charging box and the electric power of the Bluetooth® earphone are balanced, the endurance capability of the Bluetooth® earphone is prolonged, the user experience is improved, and the technical problem that the Bluetooth® earphone cannot be normally used due to the low electric power of the charging box is solved.

### BRIEF DESCRIPTION OF THE DRAWINGS

In order to more clearly illustrate the technical solutions of the embodiments of the present application or the related art, the drawings required in the description or the related art will be briefly described below. Obviously, the drawings in the following description are only a part of the drawings of the present application. For a person of ordinary skill in the art, other drawings may be obtained according to the provided drawings without creative efforts.

FIG. 1 is a schematic diagram of a hardware structure of a management device of Bluetooth® earphone charging paths according to an embodiment of the present application.

FIG. 2 is a schematic flowchart of a first embodiment of a management method of Bluetooth® earphone charging paths according to the present application.

FIG. 3 is a schematic flowchart of a second embodiment of the management method of the Bluetooth® earphone charging paths according to the present application.

FIG. 4 is a flow chart of a third embodiment of the management method of the Bluetooth® earphone charging paths according to the present application.

### DETAILED DESCRIPTION OF THE EMBODIMENTS

The technical solutions in the embodiments of the present application will be described with reference to the accompanying drawings in the embodiments of the present application. Obviously, the described embodiments are only a part and not all of the embodiments of the present application. All other embodiments obtained by a person skilled in the art based on the embodiments of the present application without creative efforts shall fall within the claimed scope of the present application

The main idea of the embodiments of the present application is that: a management method of Bluetooth® earphone charging paths detects that an external power supply is connected, acquires an electric power level of the charging box, judges whether the electric power level of the charging box is lower than a minimum working power threshold, closes a charging function of earphones and charges the charging box through the external power supply in responding to that the electric power level of the charging box is lower than the minimum working power threshold. In this way, when the external power supply is connected for charging, the state of the charging box is determined first. In order to prevent the Bluetooth® earphone from being unable to communicate due to the low electric power of the charging box, when the electric power level of the charging box is lower than the minimum working power threshold, that is, the electric power of the charging box is insufficient, the charging box is preferentially charged, and the charging function of the earphones is closed, so that the electric power of the charging box is prevented from being further consumed by the earphones. Therefore, the charging paths for the Bluetooth® earphone and the charging box are switched in real time based on the electric power of the charging box, the electric power of the charging box and the electric power of the Bluetooth® earphone are balanced, the endurance capability of the Bluetooth® earphone is prolonged, the user experience is improved, and the technical problem that the Bluetooth® earphone cannot be normally used due to the low electric power of the charging box is solved.

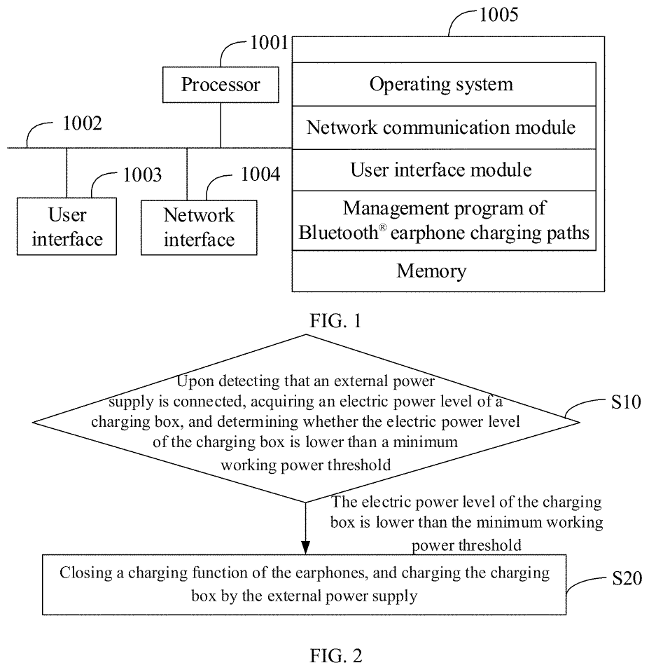

Referring to FIG. 1, FIG. 1 is a schematic structural diagram of hardware of a management device of Bluetooth® earphone charging paths according to an embodiment of the present application. In the embodiments of the present application, the management device of the Bluetooth® earphone charging paths includes a processor 1001 (e.g., a CPU), a communication bus 1002, a user interface 1003, a network interface 1004, and a memory 1005, the communication bus 1002 is used to implement connection and communication between these components. The user interface 1003 may include a display screen, an input unit such as a keyboard, and the network interface 1004 may optionally include a standard wired interface and a wireless interface (such as a Wi-Fi interface), and the memory 1005 may be a high-speed RAM memory. The memory 1005 may be a non-volatile memory, such as a magnetic disk memory, and the memory 1005 may optionally be a storage device independent of the processor 1001.

It can be understood by those skilled in the art that the hardware structure of the management device of the Bluetooth® earphone charging paths shown in FIG. 1 does not constitute a limitation on the management device of the Bluetooth® earphone charging paths, which may include more or fewer components than illustrated, or combine certain components, or have a different component arrangement.

Referring to FIG. 1 again, the memory 1005, as a computer readable storage medium in FIG. 1, may include an operating system, a network communication module, and a management program of Bluetooth® earphone charging paths.

In FIG. 1, the network communication module is mainly used for connecting a server and performing data communication with the server, and the processor 1001 may invoke the management program of the Bluetooth® earphone charging paths stored in the memory 1005, and perform the following operations:
upon detecting that an external power supply is connected, acquiring an electric power level of a charging box, and judging whether the electric power level of the charging box is lower than a minimum working power threshold; and
in responding to that the electric power level of the charging box is lower than the minimum working power threshold, closing a charging function of earphones, and charging the charging box by the external power supply.

Further, the processor 1001 may also invoke the management program of the Bluetooth® earphone charging paths stored in the memory 1005, and perform the following operations:
in responding to that the electric power level of the charging box is lower than the minimum working power threshold, marking a charging flag bit of the charging box and/or the earphones with a first identifier;
upon detecting that the charging flag bit is marked with the first identifier, closing the charging function of the earphones, and charging the charging box by the external power supply.

Further, the processor 1001 may also invoke the management program of the Bluetooth® earphone charging paths stored in the memory 1005, and perform the following operations:
upon detecting that the external power supply is connected, judging whether a charging current of the external power supply is smaller than a charging current required by the earphones;
in responding to that the charging current of the external power supply is smaller than the charging current required by the earphones, executing the operation of acquiring the electric power level of the charging box, and judging whether the electric power level of the charging box is lower than the minimum working power threshold.

Further, the processor 1001 may also invoke the management program of the Bluetooth® earphone charging paths stored in the memory 1005, and perform the following operations:
upon detecting that the electric power level of the charging box after being charged is greater than a first preset electric power threshold, marking the charging flag bit with a second identifier, and closing the charging function of the charging box;
upon detecting that the charging flag bit is marked with the second identifier, starting the charging function of the earphones, and charging the earphones by the external power supply and the charging box, where the first preset electric power threshold is greater than the minimum working power threshold.

Further, the processor 1001 may also invoke the management program of the Bluetooth® earphone charging paths stored in the memory 1005, and perform the following operations:
in responding to that the charging current of the external power supply is not smaller than the charging current required by the earphones, charging the earphones and the charging box by the external power supply.

Further, the processor 1001 may also invoke the management program of the Bluetooth® earphone charging paths stored in the memory 1005, and perform the following operations:
in responding to that the electric power level of the charging box is not lower than the minimum working power threshold, marking the charging flag bit with the second identifier, and closing the charging function of the charging box;
upon detecting that the charging flag bit is marked with the second identifier, starting the charging function of the earphones, and charging the earphones by the external power supply and the charging box.

Further, the processor 1001 may also invoke the management program of the Bluetooth® earphone charging paths stored in the memory 1005, and perform the following operations:
acquiring the electric power level of the charging box after charging the earphones, and judging whether the electric power level of the charging box after charging the earphones is lower than a second preset electric power threshold, where the second preset electric power threshold is less than the first preset electric power threshold and greater than the minimum working power threshold;
in responding to that the electric power level of the charging box after charging the earphones is lower than the second preset electric power threshold, marking the charging flag bit with the first identifier;
upon detecting that the charging flag bit is marked with the first identifier, closing the charging function of the earphones, starting the charging function of the charging box, and charging the charging box by the external power supply.

Further, the processor 1001 may also invoke the management program of the Bluetooth® earphone charging paths stored in the memory 1005, and perform the following operations:
upon detecting a disconnection instruction of the external power supply, acquiring a electric power level of the earphones, acquiring the electric power level of the charging box in responding to that the electric power level of the earphones is lower than a maximum electric power threshold of the earphones, and judging whether the electric power level of the charging box is lower than the minimum working power threshold;
in responding to that the electric power level of the charging box is lower than the minimum working power threshold, closing the charging function of the earphones to prevent the electric power of the charging box from being consumed.

The present application provides a management method of Bluetooth® earphone charging paths.

Referring to FIG. 2, FIG. 2 is a flow chart of a first embodiment of the management method of the Bluetooth® earphone charging paths of the present application.

In this embodiment, the management method of the Bluetooth® earphone charging paths includes the following operations:
operation S10, upon detecting that an external power supply is connected, acquiring an electric power level of a charging box, and determining whether the electric power level of the charging box is lower than a minimum working power threshold.

At current a TWS earphone generally includes two earphones and a charging box. The charging box mainly has two functions: one is to provide communication between the two earphones; and the another is to provide a charging function for the two earphones. Therefore, if the charging box cannot work normally due to low electric power, the TWS earphone cannot communicate, and the normal use cannot be realized. When the existing earphones and the charging box are to be charged, the earphones are generally preferentially charged, and then the charging box is charged, therefore, after the external power supply is removed for some reason, it is generally the case that the earphones has enough power but the charging box has insufficient power and cannot work normally.

In order to solve the above problem, when the external power supply is connected to charge, a state of the charging box is determined first. In order to prevent the Bluetooth® earphone from being unable to communicate due to the low electric power of the charging box, when the electric power level of the charging box is lower than the minimum working power threshold, that is, the electric power of the charging box is insufficient, the charging box is preferentially charged, and the charging function of the earphone is closed, thereby preventing the earphones from further consuming the electric power of the charging box. Therefore, the charging paths of the Bluetooth® earphone and the charging box are switched in real time based on the electric power level of the charging box, the electric power levels of the charging box and the Bluetooth® earphone are balanced, the endurance capacity of the Bluetooth® earphone is prolonged, and the user experience is improved. Specifically, in this embodiment, the TWS earphone is used as an example for description. The executive body of this embodiment can be a management terminal of Bluetooth® earphone charging paths, the electric power level of the charging box is obtained by the management terminal, and starting or closing of the charging function of the earphones is controlled based on the electric power level of the charging box. The executive body can be the earphones and the charging box. In the communication process of the TWS earphone and the charging box, the charging box sends the electric power level of the charging box to the earphones in real time, and the earphones determine whether to turn on the charging function based on the electric power level of the charging box. Upon detecting that the charging box is connected with an external power supply, for example, the external power supply is plugged into a USB interface of the charging box, the electric power level of the charging box is obtained, and the electric power level of the charging box is compared with the minimum working power threshold of the charging box. The minimum working power threshold is the minimum electric power for the normal operation of the charging box, when the charging box is lower than the minimum working power threshold, the charging box cannot communicate with the earphones.

Further, the operation S10 includes:
upon detecting the external power supply, judging whether a charging current of the external power supply is smaller than a charging current required by the earphones;
in responding to that the charging current of the external power supply is smaller than the charging current required by the earphones, executing the operation of acquiring the electric power level of the charging box, and judging whether the electric power level of the charging box is lower than the minimum working power threshold;
in responding to that the charging current of the external power supply is not lower than the charging current required by the earphones, charging the earphones and the charging box by the external power supply.

In this embodiment, when the charging current of the connected external power supply is smaller than the charging current required by the earphone, that is, the external power supply is insufficient to supply power to the earphone, the charging box is required to also charge the earphones. In order to prevent the earphones from being unable to work normally when the charging box is at a low electric power level, in responding to that the charging current of the external power supply is smaller than the charging current required by the earphone, the charging paths of the earphones and the charging box are dynamically adjusted based on the electric power level of the charging box, and the electric power of the earphones and the electric power of the charging box are balanced. If the charging current of the external power supply is larger than or equal to the charging current required by the earphones, that is, the current external power supply is sufficient to charge the earphones, the earphones and the charging box can be charged directly based on the external power supply. In an embodiment, in responding to that the charging current of the external power supply is exactly equal to the current required by the earphones, that is, the external power supply cannot simultaneously charge the earphones and the charging box, the charging paths can be adjusted by further considering the electric power level of the current charging box and the electric power level of the earphones at current, and the electric power of the charging box and the electric power of the earphones are balanced, so that the earphones and the charging box can work normally.

Operation S20, in responding to that the electric power level of the charging box is lower than the minimum working power threshold, closing a charging function of the earphones, and charging the charging box by the external power supply.

In this embodiment, if the electric power level of the charging box is lower than the minimum working power threshold, that is, the electric power of the current charging box is insufficient, the charging box should be charged preferentially. The charging function of the earphones is closed, so that the external power supply charges the charging box. Therefore, on the basis that the charging box has electric power for normal working, the earphones are then charged, and the endurance time of the earphone is prolonged.

Further, the operation S20 includes:
in responding to that the electric power level of the charging box is lower than the minimum working power threshold, marking a charging flag bit of the charging box and/or a charging flag bit of the earphones with a first identifier;

upon detecting that the charging flag bit is marked with the first identifier, closing the charging function of the earphones, and charging the charging box by the external power supply.

In this embodiment, a flag bit M configured for identifying whether the charging function of the charging box or the charging function of the earphones is started is arranged in the communication process of the earphone and the charging box, and on the basis of the flag bit, the charging function of the charging box and the charging function of the earphone are controlled to be started or closed. Specifically, when the electric power level of the charging box is lower than the minimum working power threshold, the charging box needs to be preferentially charged. The charging flag bit is set with a first identifier, such as 0, the earphones are controlled to close the charging function according to a preset control relationship, and the charging box is controlled to start the charging function, that is, the charging box can be charged by the external power supply.

Further, the management method of the Bluetooth® earphone charging paths further includes:
upon detecting a disconnection instruction of the external power supply, acquiring an electric power level of the earphones, acquiring the electric power level of the charging box in responding to that the electric power level of the earphones is lower than a maximum earphone electric power threshold of the earphones, and judging whether the electric power level of the charging box is lower than the minimum working power threshold;
in responding to that the electric power level of the charging box is lower than the minimum working power threshold, closing the charging function of the earphones to prevent the electric power of the charging box from being consumed.

In this embodiment, in order to further balance the electric power of the charging box and the electric power of the earphones, when the external power supply is detected to be removed, the electric power level of the earphones at current is obtained. When the electric power level of the earphone is lower than the maximum electric power threshold of the earphones, the earphones need to be continuously charged. The electric power level of the charging box at current is obtained, and then the state of the charging box at current is determined, if the charging box is in a state of low electric power, the earphones are not charged by the charging box. Further consumption of the electric power of the charging box with low electric power is prevented, and the endurance capability of the earphones is prolonged.

This embodiment provides a management method of Bluetooth® earphone charging paths. According to the management method of the Bluetooth® earphone charging paths, when an external power supply is detected, the electric power level of the charging box is obtained, and whether the electric power level of the charging box is lower than the minimum working power threshold is judged; if the electric power level of the charging box is lower than the minimum working power threshold, the charging function of the earphones is closed, and the charging box is charged through the external power supply. In this way, when the external power supply is connected for charging, the state of the charging box is determined first. In order to prevent the Bluetooth® earphone from being unable to communicate due to the low electric power of the charging box, when the electric power level of the charging box is lower than the minimum working power threshold, that is, the electric power level of the charging box is insufficient, the charging box is preferentially charged, the charging function of the earphones is closed, and the electric power of the charging box is prevented from being further consumed by the earphones. Therefore, the charging paths of the Bluetooth® earphone and the charging box are adjusted in real time based on the electric power of the charging box, the electric power of the charging box and the electric power of the Bluetooth® earphone are balanced, the endurance capability of the Bluetooth® earphone is prolonged, the user experience is improved, and the technical problem that the Bluetooth® earphone cannot be normally used due to the low electric power of the charging box is solved.

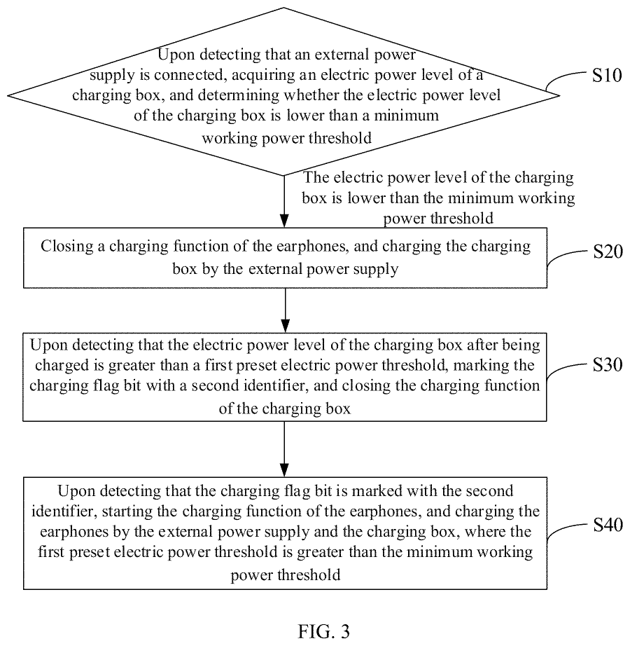

Referring to FIG. 3, FIG. 3 is a flow chart of the management method of the Bluetooth® earphone charging paths according to a second embodiment of the present application.

Based on the embodiment shown in FIG. 2, after operation S20, the method further includes:
operation S30, upon detecting that the electric power level of the charging box after being charged is greater than a first preset electric power threshold, marking the charging flag bit with a second identifier, and closing the charging function of the charging box;
operation S40, upon detecting that the charging flag bit is marked with the second identifier, starting the charging function of the earphones, and charging the earphones by the external power supply and the charging box, where the first preset electric power threshold is greater than the minimum working power threshold.

In this embodiment, based on the above embodiment, the charging current of the external power supply is smaller than the charging current required by the earphones, that is, each time only the charging box or the earphones can be charged. If it is determined that the electric power level of the charging box is lower than the minimum working power threshold X, the charging function of the charging box is started, and the flag bit M is set to be 0, the earphones determines that M is 0, the charging function of the earphones is turned off, and only the charging box is charged. The electric power level of the charging box is then continuously monitored:
(1) upon detecting that the electric power level of the charging box after being charged is greater than the first preset electric power threshold Z, the charging box turns off the charging function of the charging box, and sets the flag bit M to the second identifier, such as 1, the earphones determine that M is 1 and can start the charging function of the earphones, so as to charge the earphones by both the charging box and the external power supply;
(2) upon detecting that the electric power level of the charging box is lower than Z, the flag bit M of the charging box is still set to be 0, the charging function of the earphones is still closed, and only the charging box is charged till that the electric power level of the charging box reaches the first preset electric power threshold Z, the first preset electric power threshold is for that the charging box can work normally and can supply power to the earphones for a preset time period, and the first preset electric power threshold is greater than the minimum working power threshold, that is, Z is greater than X.

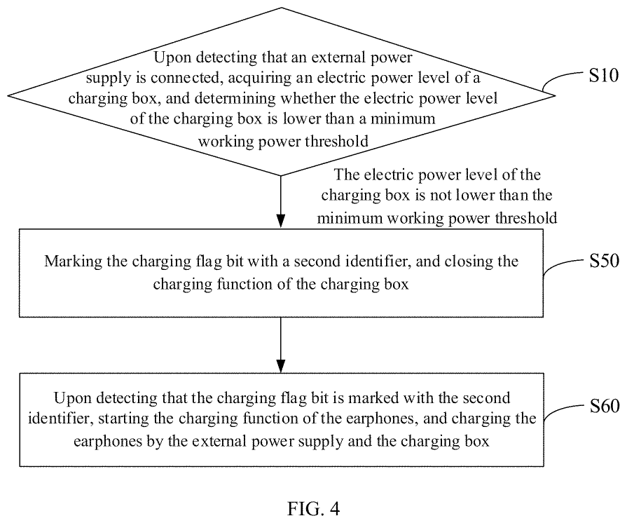

Referring to FIG. 4, FIG. 4 is a flow chart of a third embodiment of the management method of the Bluetooth® earphone charging paths according to the present application.

Based on the embodiment shown in FIG. 3, after the operation S10, the method further includes:
operation S50, in responding to that the electric power level of the charging box is not lower than the minimum working power threshold, marking the charging flag bit with the second identifier, and closing the charging function of the charging box;
operation S60, upon detecting that the charging flag bit is marked with the second identifier, starting the charging function of the earphones, and charging the earphones by the external power supply and the charging box.

Further, after the operation S60, the method further includes:
acquiring the electric power level of the charging box after charging the earphones, and judging whether the electric power level of the charging box after charging the earphones is lower than a second preset electric power threshold, where the second preset electric power threshold is less than the first preset electric power threshold and greater than the minimum working power threshold;
in responding to that the electric power level of the charging box after charging the earphones is lower than the second preset electric power threshold, marking the charging flag bit with the first identifier;
upon detecting that the charging flag bit is the first identifier, closing the charging function of the earphones, starting the charging function of the charging box, and charging the charging box by the external power supply.
in this embodiment, based on the above embodiment, the charging current of the external power supply is smaller than the charging current required by the earphones, that is, each time only the charging box or the earphones can be charged. If it is determined that the electric power level of the charging box is greater than X, the charging box turns off the charging function of the charging box, and the flag bit M is set to be 1, the earphones determines that M is 1, and can start the charging function of the earphones, and the electric power level of the charging box is continuously judged:
(1) in responding to that the electric power level of the charging box is lower than a second preset electric power threshold Y, the charging box turns on the charging function of the charging box, and sets the flag bit M to be 0; if the earphones judges that M is 0the earphones closes the charging function of the earphones, and at this moment, the charging box starts charging;
(2) in responding to that the electric power level of the charging box is greater than Y, M is still 1, the earphones continues to be charged until the electric power level of the charging box is lower than Y, Y represents that the electric power level of the charging box closes to the minimum working power threshold, and the situation that the charging box cannot work normally due to low electric power when the electric power level of the charging box reaches X and the charging box still charges the earphones is prevented, and 0<X<Y<Z<100%.

In this embodiment, in the charging process of the TWS earphone, the electric power level of the charging box is judged in real time to dynamically adjust and manage the paths, so that after the external power supply is pulled out, the electric power of the earphone and the electric power of the charging box are increased and balanced, and the endurance capacity of the TWS earphone is prolonged. For example, the battery capacity of a single earphone is 55 mAh, and the battery capacity of the charging box is 400 mAh. The existing wireless charging adopts common charging and managing paths:
when X is equal to 5%, after being charged for 2hours, the electric power of the earphone reaches 90%, the electric power of the charging box is reduced to 0, and when the charging source is removed, the charging box is completely powered off, thus the TWS earphone does not work normally.

The charging process using the management method of charging paths of the present application is as follows:

When X is equal to 5%, the charging box is charged firstly, and when the detected electric power Z is equal to 12%, the earphones are charged, at this moment, the electric power of the charging box is continuously reduced, when the electric power Y is lower than 10%, charging of the earphone is stopped, the charging box is changed, when the detected electric power Z is equal to 12%, the earphones are charged. In this way, after being charged for 2 hours, the electric power of the earphone reaches 60%, the charging source is removed, the charging box and the earphones can work normally, and the earphones can work for about 4 hours according to the power consumption of the earphones. Therefore, the charging paths of the Bluetooth® earphone and the charging box are adjusted in real time based on the electric power of the charging box, the electric power of the charging box and the electric power of the Bluetooth® earphone are balanced, the endurance capacity of the Bluetooth® earphone is prolonged, and the user experience is improved.

Further, the present application further provides a management device of Bluetooth® earphone charging paths.

The management device of the Bluetooth® earphone charging paths of the present application includes a processor, a memory, and a management program of Bluetooth® earphone charging paths stored in the memory and executable by the processor, and when the management program of the Bluetooth® earphone charging paths is executed by the processor, the operations of the management method of the Bluetooth® earphone charging paths as described above are implemented.

The method implemented when the management program of the Bluetooth® earphone charging paths is executed can refer to various embodiments of the management method of the Bluetooth® earphone charging paths of the present application, and details are omitted here.

Further, the present application further provides a non-transitory computer readable storage medium

The non-transitory computer readable storage medium of the present application stores a management program of Bluetooth® earphone charging paths, when the management program of the Bluetooth® earphone charging paths is executed by the processor, the operations of the management method of the Bluetooth® earphone charging paths as described above are implemented.

The method implemented when the management program of the Bluetooth® earphone charging paths is executed can refer to various embodiments of the management method of the Bluetooth® earphone charging paths of the present application, and details are omitted here.

Various embodiments in the present specification are described in a parallel or progressive manner, and each embodiment focuses on differences from other embodiments, and the same or similar parts of the various embodiments can make reference to each other. For the device disclosed in the embodiments, as the device corresponds to the method disclosed in the embodiments, the description of the device is simple, and the parts can refer to the description of the related parts of the method.

A person of ordinary skill in the art may further understand that the units and algorithm steps of the examples described in connection with the embodiments disclosed herein can be implemented by electronic hardware, computer software, or a combination of the two, and in order to clearly illustrate the interchangeability of hardware and software, the composition and steps of the examples have been generally described in terms of functions in the foregoing description. Whether the functions are performed by hardware or software depends on particular applications and design constraints of the technical solutions. A person skilled in the art may use different methods to implement the described functions for each particular application, but it should not be considered that the implementation goes beyond the scope of the present application.

The steps of a method or algorithm described in connection with the embodiments disclosed herein may be implemented directly by hardware, a software module executed by a processor, or a combination of the two, A software module can be placed in a random access memory (RAM), a memory, a read-only memory (ROM), an electrically programmable ROM, an electrically erasable programmable ROM, a register, a hard disk, a removable disk, a CD-ROM, or any other form of storage medium known in the art.

It should also be noted that, in this context, relational terms, such as first and second, etc. are merely used to distinguish one entity or operation from another entity or operation without necessarily requiring or implying any such actual relationship or order between these entities or operations. Moreover, the terms “including,” “comprising” or any other variation thereof, are intended to cover a non-exclusive inclusion, such that a process, a method, an article, or a device that includes a series of elements not only includes those elements, but also includes other elements not expressly listed, or an element inherent to such a process, a method, an article, or a device. In the absence of more restrictions, the element defined by the phrase “comprising one” does not exclude the presence of additional identical elements in a process, a method, an article, or a device that includes the element.

What is claimed is:

1. A management method of Bluetooth® earphone charging paths, comprising:
upon detecting that an external power supply is connected, acquiring an electric power level of a charging box, and judging whether the electric power level of the charging box is lower than a minimum working power threshold; and
in responding to that the electric power level of the charging box is lower than the minimum working power threshold, closing a charging function of earphones, and charging the charging box by the external power supply.

2. The management method of the Bluetooth® earphone charging paths according to claim 1, wherein the in responding to that the electric power level of the charging box is lower than the minimum working power threshold, closing the charging function of the earphones, and charging the charging box by the external power supply comprises:
in responding to that the electric power level of the charging box is lower than the minimum working power threshold, marking a charging flag bit of the charging box and/or the earphones with a first identifier; and
upon detecting that the charging flag bit is marked with the first identifier, closing the charging function of the earphones, and charging the charging box by the external power supply.

3. The management method of the Bluetooth® earphone charging paths according to claim 2, wherein the upon detecting that the external power supply is connected, acquiring the electric power level of the charging box, and judging whether the electric power level of the charging box is lower than the minimum working power threshold comprises:
upon detecting that the external power supply is connected, judging whether a charging current of the external power supply is smaller than a charging current required by the earphones; and
in responding to that the charging current of the external power supply is smaller than the charging current required by the earphones, executing the acquiring the electric power level of the charging box, and judging whether the electric power level of the charging box is lower the the minimum working power threshold.

4. The management method of the Bluetooth® earphone charging paths according to claim 3, wherein after the in responding to that the electric power level of the charging box is lower than the minimum working power threshold, closing the charging function of earphones, and charging the charging box by the external power supply, the method further comprises:
upon detecting that the electric power level of the charging box after being charged is greater than a first preset electric power threshold, marking the charging flag bit with a second identifier, and closing a charging function of the charging box;
upon detecting that the charging flag bit is marked with the second identifier, starting the charging function of the earphones, and charging the earphones by the external power supply and the charging box, wherein the first preset electric power threshold is greater than the minimum working power threshold.

5. The management method of the Bluetooth® earphone charging paths according to claim 3, wherein after the upon detecting that the external power supply is connected, judging whether the charging current of the external power supply is smaller than the charging current required by the earphones, the method further comprises:
in responding to that the charging current of the external power supply is not smaller than the charging current required by the earphones, charging the earphones and the charging box by the external power supply.

6. The management method of the Bluetooth® earphone charging paths according to claim 3, wherein after the upon detecting that the external power supply is connected, acquiring the electric power level of the charging box, and judging whether the electric power level of the charging box is lower than the minimum working power threshold, the method further comprises:
in responding to that the electric power level of the charging box is not lower than the minimum working power threshold, marking the charging flag bit with a second identifier, and closing a charging function of the charging box; and
upon detecting that the charging flag bit is marked with the second identifier, starting the charging function of the earphones, and charging the earphones by the external power supply and the charging box.

7. The management method of the Bluetooth® earphone charging paths according to claim 6, wherein after the upon detecting that the charging flag bit is marked with the second identifier, starting the charging function of the earphones, and charging the earphones by the external power supply and the charging box, the method further comprises:
acquiring the electric power level of the charging box after charging the earphones, and judging whether the electric power level of the charging box after charging the earphones is lower than a second preset electric power threshold, wherein the second preset electric power threshold is less than the first preset electric power threshold and greater than the minimum working power threshold;
in responding to that the electric power level of the charging box after charging the earphones is lower than the second preset electric power threshold, marking the charging flag bit with the first identifier; and
upon detecting that the charging flag bit is marked with the first identifier, closing the charging function of the earphones, starting the charging function of the charging box, and charging the charging box by the external power supply.

8. The management method of the Bluetooth® earphone charging paths according to claim 1, further comprising:
upon detecting a disconnection instruction of the external power supply, acquiring a electric power level of the earphones, acquiring the electric power level of the charging box in responding to that the electric power level of the earphones is lower than a maximum electric power threshold of the earphones, and judging whether the electric power level of the charging box is lower than the minimum working power threshold; and
in responding to that the electric power level of the charging box is lower than the minimum working power threshold, closing the charging function of the earphones to prevent the electric power of the charging box from being consumed.

9. A management device of Bluetooth® earphone charging paths, comprising a processor, a memory, and a management program of the Bluetooth® earphone charging paths stored in the memory and executable by the processor, wherein when the management program of the Bluetooth® earphone charging paths is executed by the processor, operations of a management method of the Bluetooth® earphone charging paths are implemented:
upon detecting that an external power supply is connected, acquiring an electric power level of a charging box, and judging whether the electric power level of the charging box is lower than a minimum working power threshold; and
in responding to that the electric power level of the charging box is lower than the minimum working power threshold, closing a charging function of earphones, and charging the charging box by the external power supply.

10. The management device of the Bluetooth® earphone charging paths according to claim 9, wherein the in responding to that the electric power level of the charging box is lower than the minimum working power threshold, closing the charging function of the earphones, and charging the charging box by the external power supply comprises:
in responding to that the electric power level of the charging box is lower than the minimum working power threshold, marking a charging flag bit of the charging box and/or the earphones with a first identifier; and
upon detecting that the charging flag bit is marked with the first identifier, closing the charging function of the earphones, and charging the charging box by the external power supply.

11. The management device of the Bluetooth® earphone charging paths according to claim 10, wherein the upon detecting that the external power supply is connected, acquiring the electric power level of the charging box, and judging whether the electric power level of the charging box is lower than the minimum working power threshold comprises:
upon detecting that the external power supply is connected, judging whether a charging current of the external power supply is smaller than a charging current required by the earphones; and
in responding to that the charging current of the external power supply is smaller than the charging current required by the earphones, executing the acquiring the electric power level of the charging box, and judging whether the electric power level of the charging box is lower than the minimum working power threshold.

12. The management device of the Bluetooth® earphone charging paths according to claim 11, wherein when the management program of the Bluetooth® earphone charging paths is executed by the processor, after the in responding to that the electric power level of the charging box is lower than the minimum working power threshold, closing the charging function of earphones, and charging the charging box by the external power supply, following operations are further implemented:
upon detecting that the electric power level of the charging box after being charged is greater than a first preset electric power threshold, marking the charging flag bit with a second identifier, and closing a charging function of the charging box;
upon detecting that the charging flag bit is marked with the second identifier, starting the charging function of the earphones, and charging the earphones by the external power supply and the charging box, wherein the first preset electric power threshold is greater than the minimum working power threshold.

13. The management device of the Bluetooth® earphone charging paths according to claim 11, wherein when the management program of the Bluetooth® earphone charging paths is executed by the processor, after the upon detecting that the external power supply is connected, judging whether the charging current of the external power supply is smaller than the charging current required by the earphones, following operations are further implemented:
in responding to that the charging current of the external power supply is not smaller than the charging current required by the earphones, charging the earphones and the charging box by the external power supply.

14. The management device of the Bluetooth® earphone charging paths according to claim 11, wherein when the management program of the Bluetooth® earphone charging paths is executed by the processor, after the upon detecting that the external power supply is connected, acquiring the electric power level of the charging box, and judging whether the electric power level of the charging box is lower than the minimum working power threshold, following operations are further implemented:
in responding to that the electric power level of the charging box is not lower than the minimum working power threshold, marking the charging flag bit with a second identifier, and closing a charging function of the charging box; and
upon detecting that the charging flag bit is marked with the second identifier, starting the charging function of the earphones, and charging the earphones by the external power supply and the charging box.

15. A non-transitory computer readable storage medium, wherein a management program of Bluetooth® earphone charging paths is stored in the computer readable storage medium, when the management program of the Bluetooth® earphone charging paths is executed by a processor, the operations of a management method of the Bluetooth® earphone charging paths are implemented:
upon detecting that an external power supply is connected, acquiring an electric power level of a charging box, and judging whether the electric power level of the charging box is lower than a minimum working power threshold; and
in responding to that the electric power level of the charging box is lower than the minimum working power threshold, closing a charging function of earphones, and charging the charging box by the external power supply.

16. The non-transitory computer readable storage medium according to claim 15, wherein the in responding to that the electric power level of the charging box is lower than the minimum working power threshold, closing the charging function of the earphones, charging the charging box by the external power supply comprises:
in responding to that the electric power level of the charging box is lower than the minimum working power threshold, marking a charging flag bit of the charging box and/or the earphones with a first identifier; and
upon detecting that the charging flag bit is marked with the first identifier, closing the charging function of the earphones, and charging the charging box by the external power supply.

17. The non-transitory computer readable storage medium according to claim 16, wherein the upon detecting that the external power supply is connected, acquiring the electric power level of the charging box, and judging whether the electric power level of the charging box is lower than the minimum working power threshold comprises:
upon detecting that the external power supply is connected, judging whether a charging current of the external power supply is smaller than a charging current required by the earphones; and
in responding to that the charging current of the external power supply is smaller than the charging current required by the earphones, executing the acquiring the electric power level of the charging box, and judging whether the electric power level of the charging box is lower than the minimum working power threshold.

18. The non-transitory computer readable storage medium according to claim 17, wherein when the management program of the Bluetooth® earphone charging paths is executed by the processor, after the in responding to that the electric power level of the charging box is lower than the minimum working power threshold, closing the charging function of earphones, and charging the charging box by the external power supply, following operations are further implemented:
upon detecting that the electric power level of the charging box after being charged is greater than a first preset electric power threshold, marking the charging flag bit with a second identifier, and closing a charging function of the charging box;
upon detecting that the charging flag bit is marked with the second identifier, starting the charging function of the earphones, and charging the earphones by the external power supply and the charging box, wherein the first preset electric power threshold is greater than the minimum working power threshold.

19. The non-transitory computer readable storage medium according to claim 17, wherein when the management program of the Bluetooth® earphone charging paths is executed by the processor, after the upon detecting that the external power supply is connected, judging whether the charging current of the external power supply is smaller than the charging current required by the earphones, following operations are further implemented:
in responding to that the charging current of the external power supply is not smaller than the charging current required by the earphones, charging the earphones and the charging box by the external power supply.

20. The non-transitory computer readable storage medium according to claim 17, wherein when the management program of the Bluetooth® earphone charging paths is executed by the processor, after the upon detecting that the external power supply is connected, acquiring the electric power level of the charging box, and judging whether the electric power level of the charging box is lower than the minimum working power threshold, following operations are further implemented:
in responding to that the electric power level of the charging box is not lower than the minimum working power threshold, marking the charging flag bit with a second identifier, and closing a charging function of the charging box; and
upon detecting that the charging flag bit is marked with the second identifier, starting the charging function of the earphones, and charging the earphones by the external power supply and the charging box.
